(19) United States
(12) Patent Application Publication
(10) Pub. No.: US 2002/0132395 A1
(43) Pub. Date: Sep. 19, 2002

(54) Body contact in SOI devices by electrically weakening the oxide under the body

(75) Inventors: Sundar K. Iyer, Beacon, NY (US); Devendra K. Sadana, Pleasantville, NY (US)

Correspondence Address: Eric W. Petraske, Intellectual Property Law, IBM Corporation, Dept. 18G, Building 300-482, 2070 Route 52, Hopewell Junction, NY, 12533, US

(73) Assignee: INTERNATIONAL BUSINESS MACHINES CORPORATION, Armonk, NY (US)

(21) Appl. No.: 09/810,236

(22) Filed: Mar. 16, 2001

(51) Int. Cl. H01L 21/00

(52) U.S. Cl. 438/149

(57) ABSTRACT

An SOI substrate contact is provided to the bodies of transistors fabricated in an SOI silicon wafer by selectively making the insulating layer below the bodies leaky. This is achieved by implanting below a set of transistor body locations a dose of ions having an energy such that the implanted region extends vertically through the buried insulator between the body and the wafer substrate, after which a voltage is applied sufficient to break down the oxide and establish a conductive path between the body and the substrate.

### FIELD OF THE INVENTION

The field of the invention is SOI integrated circuits having body contacts.

### BACKGROUND OF THE INVENTION

In SOI integrated circuits, a well known problem is the buildup of holes/electrons in the body of the NFETs and PFETs, respectively, changing the transistor drive. The standard solution is to make a contact to the transistor body, providing a path to ground to drain away the charge. Unfortunately, most body contacts consume precious silicon area. In a few cases, the contact can be made by selectively implanting oxygen only under the source and drain, or by etching a hole through the buried oxide (SiO₂) and filling it with a conductor. Selective implantation is expensive and time-consuming. It is not suitable for small feature size transistors in existing technology. In addition, it is necessary to make some sort of alignment reference in order to place the transistors in the correct locations. Etching a hole under the transistor body and filling in an insulator requires many additional processing steps and is expensive. The quality of the silicon in the transistor body will also deteriorate during this processing.

### SUMMARY OF THE INVENTION

The invention relates to a method of forming a body contact by establishing a conductive path below the transistor body through the buried insulator down to the silicon substrate.

A feature of the invention is the implantation of ions through the transistor body and into the buried insulator, followed by the application of a voltage sufficient to break down the oxide and establish a conductive path between the transistor body and the substrate.

### BRIEF DESCRIPTION OF THE DRAWINGS

FIGS. 1 through 4 show various stages in the process.

FIG. 5 shows a completed transistor.

FIG. 6 shows the application of bias voltages to wells formed in the substrate.

### DESCRIPTION OF THE PREFERRED EMBODIMENT

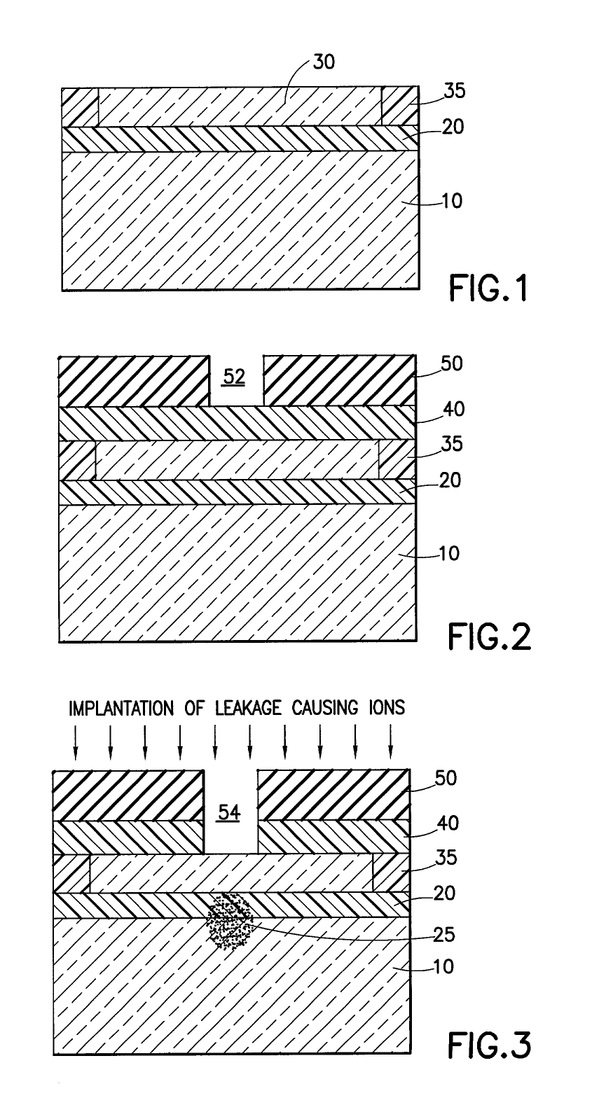

Referring to FIG. 1, there is shown in cross section a semiconductor active area 30 (illustratively silicon) bounded by shallow trench isolation (STI) members 35. Area 30 is placed on top of an insulating layer 20. The whole is supported by bulk substrate 10, illustratively doped p-type. Illustratively layer 20 is formed by implanting oxygen followed by high temperature (−1300° C.) annealing, referred to in the literature as the SIMOX method (Separation by IMplantation of OXygen).

A transistor will be formed in active area 30, the body of which will be connected through layer 20 to substrate 10. With the conductive path formed according to the invention, there will be a path to drain away charge from the transistor body in operation.

FIG. 2 shows the result of depositing a layer of oxide (SiO₂) 40 and a layer of resist, 50, forming an aperture 52 in the resist. The total thickness of resist and oxide will be selected to block the ions that will be implanted from reaching device layer 30. Illustratively, oxide layer 40 has a thickness of about 500 nm and resist 50 has a thickness of about 1,000 nm. The oxide and resist can block ions implanted with an energy of up to 200 keV from reaching the silicon outside the aperture.

FIG. 3 shows the result of etching an aperture 54 in oxide 40 and implanting a dose of ions through the aperture and into the buried oxide (BOX) and just below it, the ion-implanted region being denoted with the numeral 25. If needed, the energy of the ions may be varied so that the ionimplanted region extends all the way through the oxide. The value of the ion energy will depend on the thickness of device layer 30 and BOX 20. Doses on the order of 10¹³/cm² have been found to significantly lower the electrical breakdown field in a (high integrity) gate oxide of 2.6 nm thickness from ≈18 MV/cm to ≈13 MV/cm. The magnitude of the dose will depend on the thickness of the region to be implanted. SIMOX wafers are preferable to bonded wafers because they have considerable amounts of unreacted silicon that can contribute to the conductive path. Preferably, the etch through oxide 40 is a directional reactive ion etch so that the aperture has straight walls.

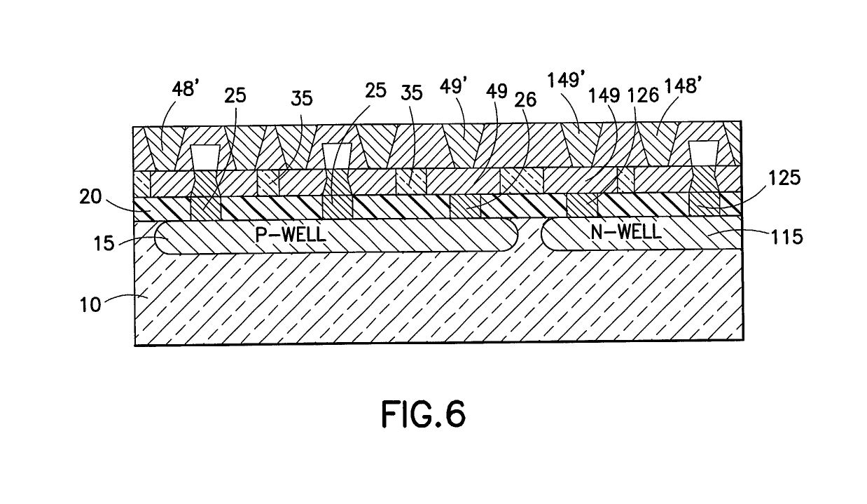

It has been found that Indium is satisfactory for lowering the breakdown voltage of oxide, but those skilled in the art will readily be able to make their own choice. Other ions suitable for producing lower breakdown voltages include ions at least as heavy as Si, especially in columns III and IV of the periodic table, e.g. Ga, Ti, Si, Ge, Sn, Pb, Au, and Fe. If desired, the transistor body may be connected through a well that, in turn, is connected to a contact on the wafer surface. Such a structure is shown in FIG. 6, in which a p-well 15 and an n-well 115 have body contacts 25 and 125, respectively. Contact 25 will be made using p-type ions (e.g. B) and contact 125 will be made using n-type ions (e.g. P, As, or Sb). P-well 15 has an additional contact 26 that contacts a p-type implanted area 49 in the device layer. Area 49, in turn, has a vertical contact member 49′ that connects to a bias source. Similarly, N-well 115 has a contact 126 through BOX 20, an N-type implanted area 126 in the BOX, an N-type implanted area 149 and a contact member 149′. Thus, both wells can be biased as desired, e.g. negative or ground for well 15 and positive for well 115.

After electrically weakening the oxide, by implantation, the processing of the transistor may continue. One method is to use the masking oxide to from a self-aligned gate above body contact 25. Referring now to FIG. 4, a gate oxide 42 has been grown in the bottom of aperture 54 and a layer of polysilicon has been deposited and polished by chemical-mechanical polishing, using the top surface of oxide 40 as a polish stop to form gate 45. Another alternative method of processing would be to remove the deposited resist and oxide layer 40 after the implantation of contact 25. The transistor may then be fabricated using a conventional process. Since the lithography for BOX weakening was aligned with the STI litho marks as a reference, the same reference could be used for gate definition. This will allow the electrically weakened BOX areas to appear directly under the bodies of the NFETs and PFETs. This second method is not self-aligned, but the alignment of contact 25 with the body is not critical.

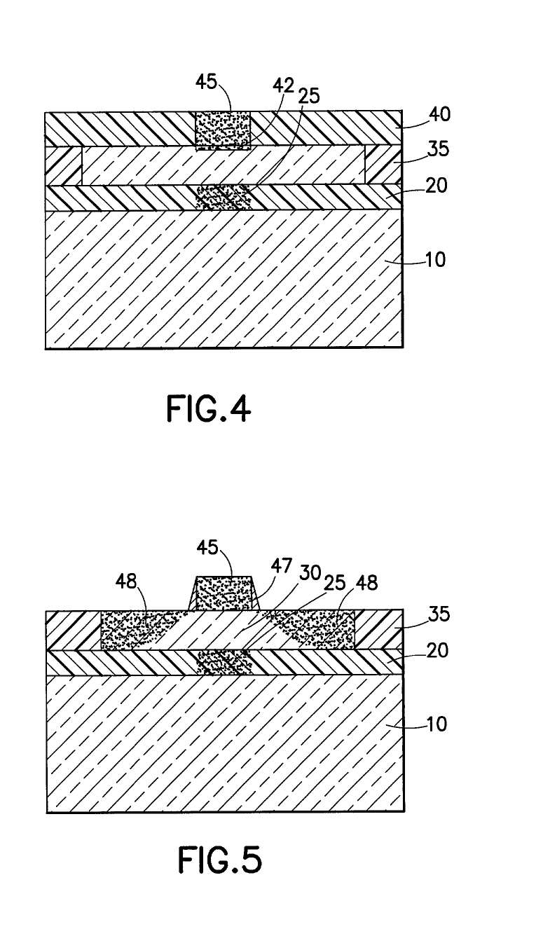

FIG. 5 shows the completed transistor with gate 45, sidewalls 47, source/drain 48 and body contact 25. Other conventional steps, such as forming suicide on the gate, source and drain, and forming interconnects and interlayer dielectric to connect transistors to form the circuit will be referred to collectively as “completing the circuit”. Similarly, conventional preliminary steps, such as forming pad oxide and nitride, forming STI, threshold adjustment implants, and the like will be referred to for the purpose of the claims as “preparing the substrate”.

At any convenient time after the ion implantation, an appropriate voltage may be applied to break down the oxide. The voltage should produce an electric field across the BOX that is above the breakdown value for the “weakened” areas of the BOX, but less than the breakdown voltage for the unimplanted BOX areas. This may be done by exposing the wafer to a plasma with bias conditions set such that the plasma voltage contributes to the breakdown. Alternatively, a temporary layer of metal could be deposited or plated (or a conductive liquid may be coated on the top surface) to provide a contact, the other contact being applied to the substrate. The magnitude of voltage is preferably less than about 50 V for a BOX thickness of 100 nm, but will vary with the magnitude of the ion dose, ion species, etc. The term “break down” as used here means that the insulating property of the oxide is lost and the oxide is “leaky” (less than about 10⁶ ohms). It does not have to be a conductor, merely to have a high enough leakage that the holes will drain away in a steady state.

Preferably, this weakening implant is performed before the gate oxide is grown in order to protect the gate oxide from implant damage.

While the invention has been described in terms of a single preferred embodiment, those skilled in the art will recognize that the invention can be practiced in various versions within the spirit and scope of the following claims.

We claim:

1. A method of forming an integrated circuit comprising the steps of:
preparing a semiconductor wafer having a semiconductor device layer above an insulator layer that is above a semiconductor substrate;
implanting a dose of ions in a set of transistor body locations in said device layer, said dose of ions being implanted with energies such that a distribution of ions extends from said body locations through said insulator layer and into said substrate;
applying a voltage between said device layer and said substrate such that the material of said insulator layer is broken down and becomes conductive; and
forming a set of transistors and connecting said set of transistors to form said integrated circuit.

2. A method according to claim 1, in which said device layer is silicon and said insulator is oxide.

3. A method according to claim 2, in which said ions are from column III of the Periodic Table.

4. A method according to claim 2, in which said ions are from column IV of the Periodic Table.

5. A method according to claim 2, in which said ions are taken from the group comprising Si, Ga, Ge, In, Sn, TI, Au, and Pb.

6. A method according to claim 2, in which an NFET set of transistor bodies is doped p-type and a region of said substrate below said set of transistor bodies is doped p-type.

7. A method according to claim 2, in which a PFET set of transistor bodies is doped n-type and a region of said substrate below said set of transistor bodies is doped n-type.
